(19) United States
(12) Patent Application Publication
(10) Pub. No.: US 2025/0306451 A1
(43) Pub. Date: Oct. 2, 2025

(54) PELLICLE FILM, PELLICLE, AND METHOD FOR MEASURING STANDARD DEVIATION OF ORIENTATION ANGLE OF CARBON NANOTUBES INCLUDED IN PELLICLE FILM

(71) Applicant: LINTEC Corporation, Tokyo (JP)

(72) Inventors: Shuhei KUBO, Tokyo (JP); Isao ICHIKAWA, Tokyo (JP); Jun KAWAHARA, Tokyo (JP); Takahiro UEDA, Phoenix, AZ (US); Takumi FURUYA, Phoenix, AZ (US); Yoshiaki HAGIHARA, Tokyo (JP)

(21) Appl. No.: 18/620,810

(22) Filed: Mar. 28, 2024

(51) Int. Cl. G03F 1/64; G03F 1/70; G03F 1/82

(52) U.S. Cl. CPC G03F 1/64; G03F 1/70; G03F 1/82

(57) ABSTRACT

A pellicle film has a porous structure. The pellicle film includes carbon nanotubes. The pellicle film has a first pellicle film surface and a second pellicle film surface on a side opposite to the first pellicle film surface, and a standard deviation of an orientation angle of the carbon nanotubes is 8.0 degrees or less, the standard deviation being determined based on an approximate ellipse of a power spectrum image acquired by subjecting an image obtained by imaging the first pellicle film surface or the second pellicle film surface of the pellicle film to two-dimensional Fourier transform.

### TECHNICAL FIELD

The present invention relates to a pellicle film, a pellicle, and a method for measuring a standard deviation of an orientation angle of carbon nanotubes included in a pellicle film.

### BACKGROUND ART

In a process of manufacturing a semiconductor device or the like, for example, a photoresist is applied to a substrate such as a semiconductor wafer, the substrate having the photoresist thereon is irradiated with light using a photomask, and the photoresist is removed to thereby form a desired circuit pattern on the substrate.

If light is applied in a state where foreign matter adheres to the photomask, the adhering foreign matter may adversely affect the circuit pattern formed on the substrate. Therefore, in order to suppress adhesion of foreign matter to the photomask, a pellicle that includes a pellicle film for capturing foreign matter is used in some cases. The pellicle is disposed above the photomask at a distance such that the pellicle film is not in contact with the photomask.

In recent years, use of extreme ultra violet (EUV) has been studied in order to form a finer circuit pattern. EUV means light with a wavelength in a range from 1 nm to 100 nm. For example, specifically, a light beam with a wavelength of about 13.5 nm±0.3 nm is being used as EUV. When a pellicle film is irradiated with EUV, although the EUV is transmitted through the pellicle film, a part of the radiated EUV is absorbed by the pellicle film. The light energy of absorbed EUV is converted into thermal energy, and the temperature of the pellicle film is thereby increased. Thus, the pellicle film is required to have, for example, transparency to EUV, heat resistance, and durability.

In a pellicle used in a step of forming a circuit pattern using EUV, carbon nanotubes have been studied as one of the materials used for a pellicle film included in the pellicle.

For example, Patent Literature 1 (JP No. 2023-106455 A) discloses a pellicle film for exposure, the pellicle film including a carbon nanotube film containing carbon nanotubes. In the carbon nanotube film disclosed in Patent Literature 1, the transmittance of EUV light at a wavelength of 13.5 nm is 80% or more, the thickness is in a range from 1 nm to 50 nm, and 3σ of a reflectance is 15% or less.

In the pellicle film including carbon nanotubes and disclosed in Patent Literature 1, uniformity of EUV transmittance is enhanced by enhancing uniformity of the thickness of the pellicle film. However, in the pellicle film disclosed in Patent Literature 1, the uniformity of the thickness is considered only from a macroscopic viewpoint, and variation in a microscopic structure due to overlapping of carbon nanotube bundles is not considered. In the existing pellicle film, there is a concern that large variation in the microscopic structure may cause a decrease in the mechanical strength. Thus, further improvements have been required for the pellicle film.

### SUMMARY OF THE INVENTION

An object of the invention is to provide a pellicle film including carbon nanotubes, the pellicle film having excellent mechanical strength, a pellicle including the pellicle film, and a method for measuring a standard deviation of an orientation angle of carbon nanotubes included in the pellicle film.

[1]A pellicle film having a porous structure,
in which the pellicle film includes carbon nanotubes,
the pellicle film has a first pellicle film surface and a second pellicle film surface on a side opposite to the first pellicle film surface, and
a standard deviation of an orientation angle of the carbon nanotubes is 8.0 degrees or less, the standard deviation being determined based on an approximate ellipse of a power spectrum image acquired by subjecting an image obtained by imaging the first pellicle film surface or the second pellicle film surface of the pellicle film to two-dimensional Fourier transform.
   [2] The pellicle film according to [1],
in which the standard deviation of the orientation angle of the carbon nanotubes is in a range from 0.5 degrees to 8.0 degrees.
   [3] The pellicle film according to [1] or [2],
in which the image obtained by imaging the first pellicle film surface or the second pellicle film surface is an image captured with a scanning electron microscope.
   [4] The pellicle film according to any one of [1] to [3],
in which the carbon nanotubes have a length in a range from 0.1 μm to 1,000 μm.
   [5] The pellicle film according to any one of [1] to [4],
in which the carbon nanotubes have a cross-sectional diameter in a range from 0.2 nm to 50 nm.
   [6] The pellicle film according to any one of [1] to [5],
being a free-standing pellicle film.
   [7]A pellicle including:
the pellicle film according to any one of [1] to [6]; and
a support that has a frame and an opening surrounded by the frame and that supports the pellicle film.
   [8]A method for measuring a standard deviation of an orientation angle of carbon nanotubes included in a pellicle film having a porous structure, the method including:
preparing a pellicle film including carbon nanotubes and having a first pellicle film surface and a second pellicle film surface on a side opposite to the first pellicle film surface;
imaging the first pellicle film surface or the second pellicle film surface of the prepared pellicle film with a scanning electron microscope to acquire image data on the surface of the pellicle film;
subjecting the acquired image data to two-dimensional Fourier transform to acquire a power spectrum image;
drawing, for the acquired power spectrum image, an approximate ellipse from an angle distribution diagram of a mean amplitude and calculating a mean value of orientation strength in a radial direction of the approximate ellipse;
calculating, for the calculated mean value of the orientation strength, an inclination of the approximate ellipse based on an elliptic equation to acquire an orientation angle; and
calculating a standard deviation of the orientation angle.

An aspect of the invention can provide a pellicle film including carbon nanotubes, the pellicle film having excellent mechanical strength, a pellicle including the pellicle film, and a method that enables measurement of a standard deviation of an orientation angle of carbon nanotubes included in a pellicle film having excellent mechanical strength.

### BRIEF DESCRIPTION OF DRAWINGS

FIG. 1 is a schematic sectional view illustrating an example of a pellicle film according to an exemplary embodiment of the invention.

FIG. 2 is a schematic view illustrating an example of an angle distribution diagram of a mean amplitude of a pellicle film according to the exemplary embodiment.

FIG. 3 is a schematic plan view illustrating an example of a pellicle according to the exemplary embodiment.

FIG. 4 is a sectional view taken along line IV-IV in FIG. 3.

### DETAILED DESCRIPTION

Hereinafter, a pellicle film, a pellicle, and a method for measuring a standard deviation of an orientation angle of carbon nanotubes included in a pellicle film according to preferred exemplary embodiments of the invention will be described.

### Pellicle Film

A pellicle film according to the exemplary embodiment is a pellicle film having a porous structure. The pellicle film includes carbon nanotubes. The pellicle film has a first pellicle film surface and a second pellicle film surface on a side opposite to the first pellicle film surface. The pellicle film has a standard deviation of an orientation angle of the carbon nanotubes of 8.0 degrees or less, the standard deviation being determined based on an approximate ellipse of a power spectrum image acquired by subjecting an image obtained by imaging the first pellicle film surface or the second pellicle film surface of the pellicle film to two-dimensional Fourier transform.

The pellicle film according to the exemplary embodiment has excellent mechanical strength due to the above configuration. Since the pellicle film according to the exemplary embodiment has a standard deviation of an orientation angle of the carbon nanotubes of 8.0 degrees or less, the standard deviation being determined by the above method, the microscopic orientation angle of the carbon nanotubes is considered to be uniform. Accordingly, it is considered that the pellicle film according to the exemplary embodiment is in a state in which the surface of the pellicle film has a substantially uniform structure, and has improved mechanical strength.

In the pellicle film according to the exemplary embodiment described later, a method for measuring a standard deviation of an orientation angle of carbon nanotubes included in the pellicle film enables the microscopic orientation angle of carbon nanotubes to be numerically expressed. By numerically expressing the orientation angle of carbon nanotubes at a plurality of positions, variation in the orientation angle of the entire pellicle film is determined. Therefore, according to the method for measuring a standard deviation of an orientation angle of carbon nanotubes included in a pellicle film according to the exemplary embodiment, it is possible to measure the standard deviation of the orientation angle of carbon nanotubes included in a pellicle film having excellent mechanical strength.

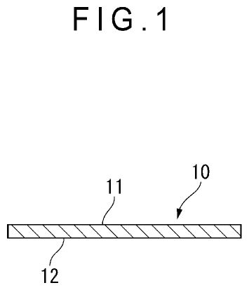

Referring to FIG. 1, FIG. 1 schematically illustrates a cross section of a pellicle film according to the exemplary embodiment. A pellicle film 10 has a porous structure and includes carbon nanotubes. The pellicle film 10 has a first pellicle film surface 11 and a second pellicle film surface 12 on a side opposite to the first pellicle film surface 11. In the pellicle film 10, a standard deviation of an orientation angle of the carbon nanotubes included in the pellicle film 10 is 8.0 degrees or less. The standard deviation of the orientation angle of the carbon nanotubes included in the pellicle film 10 is determined based on an approximate ellipse of a power spectrum image acquired by subjecting an image obtained by imaging the first pellicle film surface 11 or the second pellicle film surface 12 to two-dimensional Fourier transform. Specifically, the standard deviation of the orientation angle can be measured by a method for measuring a standard deviation of an orientation angle of carbon nanotubes included in a pellicle film according to the exemplary embodiment described later. The image obtained by imaging the first pellicle film surface 11 or the second pellicle film surface 12 is preferably an image captured with a scanning electron microscope (SEM).

In the present specification, for convenience, the terms “first pellicle film surface” and “second pellicle film surface” of the pellicle film are used in order to clarify the positional relationship between one surface and the other surface. Therefore, in some cases, both the first pellicle film surface and the second pellicle film surface can be interchangeably used, and the first pellicle film surface and the second pellicle film surface can be used without distinction.

An example of the pellicle film according to the exemplary embodiment has been described above with reference to FIG. 1. The pellicle film according to the exemplary embodiment is not limited thereto. The pellicle film according to the exemplary embodiment may employ any of various forms as long as the above-described advantages are obtained.

The carbon nanotubes included in the pellicle film according to the exemplary embodiment are not particularly limited and are preferably at least one selected from the group consisting of multi-walled carbon nanotubes (MWCNT), few-walled carbon nanotubes (FWCNT), double-walled carbon nanotubes (DWCNT), and single-walled carbon nanotubes (SWCNT).

The carbon nanotubes are obtained by a publicly known production method such as an arc discharge method, a laser ablation method, or chemical vapor deposition.

The length of the carbon nanotubes is preferably, for example, in a range from 0.1 μm to 1,000 μm.

The length of the carbon nanotubes is more preferably 0.5 μm or more, still more preferably 1 μm or more.

The length of the carbon nanotubes is more preferably 600 μm or less, still more preferably 400 μm or less.

The cross-sectional diameter of the carbon nanotubes is preferably in a range from 0.2 nm to 50 nm.

The cross-sectional diameter of the carbon nanotubes is more preferably 0.5 nm or more, still more preferably 1 nm or more.

The cross-sectional diameter of the carbon nanotubes is more preferably 30 nm or less, still more preferably 20 nm or less.

Herein, the cross-sectional diameter may be simply referred to as a diameter.

In the pellicle film according to the exemplary embodiment, the standard deviation of the orientation angle of carbon nanotubes is determined based on an approximate ellipse of a power spectrum image acquired by subjecting an image obtained by imaging the first pellicle film surface or the second pellicle film surface to two-dimensional Fourier transform. The standard deviation of the orientation angle of carbon nanotubes in the pellicle film according to the exemplary embodiment is 8.0 degrees or less. From the viewpoint of more easily improving the mechanical strength of the pellicle film, the standard deviation of the orientation angle of carbon nanotubes is preferably 7.0 degrees or less, more preferably 6.0 degrees or less, still more preferably 5.0 degrees or less, and still further more preferably 4.0 degrees or less.

The lower limit of the standard deviation of the orientation angle of carbon nanotubes is not particularly limited. From the viewpoint of more easily improving the mechanical strength of the pellicle film, the lower limit of the standard deviation of the orientation angle of carbon nanotubes is preferably close to 0 degrees, may be more than 0 degrees, may be 0.5 degrees or more, and may be 1 degree or more. The standard deviation of the orientation angle of carbon nanotubes may be, for example, in a range from 0.5 degrees to 8.0 degrees.

### Method for Measuring Standard Deviation of Orientation Angle of Carbon Nanotubes Included in Pellicle Film

A method for measuring a standard deviation of an orientation angle of carbon nanotubes included in a pellicle film having a porous structure according to the exemplary embodiment includes step (S1) to step (S6) below. Use of the measurement method described below as a method for measuring a standard deviation of an orientation angle of carbon nanotubes included in a pellicle film enables the microscopic orientation angle of carbon nanotubes to be numerically expressed and enables the standard deviation of the orientation angle to be evaluated as an indicator of uniformity of the structure of the pellicle film. As a result, an improvement in the mechanical strength of the pellicle film can be evaluated.

Step (S1): a step of preparing a pellicle film including carbon nanotubes and having a first pellicle film surface and a second pellicle film surface on a side opposite to the first pellicle film surface.

Step (S2): a step of imaging the first pellicle film surface or the second pellicle film surface of the prepared pellicle film with a scanning electron microscope (hereinafter, may be referred to as SEM) to acquire image data on the surface of the pellicle film.

Step (S3): a step of subjecting the acquired image data to two-dimensional Fourier transform to acquire a power spectrum image.

Step (S4): a step of drawing, for the acquired power spectrum image, an approximate ellipse from an angle distribution diagram of a mean amplitude and calculating a mean value of orientation strength in a radial direction of the approximate ellipse.

Step (S5): a step of calculating, for the calculated mean value of the orientation strength, an inclination of the approximate ellipse based on an elliptic equation to acquire an orientation angle.

Step (S6): a step of calculating a standard deviation of the orientation angle.

In step (S1), first, a pellicle film having a porous structure according to the exemplary embodiment is prepared. The pellicle film prepared in step (S1) may be the pellicle film 10 illustrated in FIG. 1. The pellicle film 10 may be specifically, for example, a pellicle film obtained by a preferred method for producing a pellicle film described later.

In step (S2), the pellicle film prepared in step (S1) is imaged with an SEM to acquire image data on a surface of the pellicle film. The image data on the surface of the pellicle film may be image data obtained by imaging either the first pellicle film surface or the second pellicle film surface. Imaging conditions are not limited as long as the orientation angle of carbon nanotubes can be evaluated. For example, the accelerating voltage may be in a range from 0.8 kV to 8.0 kV, and the imaging magnification may be in a range from 1,000 times to 100,000 times.

In step (S3), the image data acquired in step (S2) is subjected to two-dimensional Fourier transform to acquire a power spectrum image. In step (S3), first, an SEM image is read with the imread function from the image data of the SEM image acquired in step (S2), and pixel values of the read SEM image are acquired as a numerical array. The imread function used may be, for example, the imread function of analysis software (Mathworks, “MATLAB”). Next, the read SEM image is trimmed into a predetermined square region L. The trimmed square region may have a size of, for example, 700×700 pixels. Next, the numerical array in the trimmed region is subjected to two-dimensional Fourier transform using the fft2 function to acquire a power spectrum image. The fft2 function used may be, for example, the fft2 function of analysis software (Mathworks, “MATLAB”). This procedure can provide a power spectrum image obtained by subjecting the image data of the SEM image acquired in step (S2) to two-dimensional Fourier transform.

In step (S4), for the power spectrum image acquired in step (S3), an approximate ellipse is drawn from an angle distribution diagram of a mean amplitude. A mean value of orientation strength in a radial direction of the approximate ellipse is calculated. Here, the radial direction indicates a direction from the central coordinates toward a coordinate position corresponding to the outer circumference of the approximate ellipse. In step (S4), the real part of the power spectrum image acquired in step (S3) is acquired as an absolute value by the abs function. The abs function used may be, for example, the abs function of analysis software (Mathworks, “MATLAB”). Next, the central coordinates of a power spectrum array are calculated on the basis of the absolute value of the real part of the acquired power spectrum image. A distance R and an angle θ between each pixel and the central coordinates are calculated and stored in the array. On the basis of the calculated array of the distance R and angle θ, a mean value in pixel values in any angle range Δθ and at a distance of 1/2 (L/2) or less of the region L is calculated. For example, when Δθ is 1 degree, pixel values are acquired in a range between 0 degrees and 1 degree and at a distance R of L/2 or less (R≤L/2), and the mean value is calculated. Similarly, pixel values are acquired in a range between 1 degree and 2 degrees and at a distance R of L/2 or less (R≤L/2), and the mean value is calculated. Subsequently, acquiring pixel values in a range between n degrees and n+1 degrees and at a distance R of L/2 or less (R≤L/2) and calculating the mean value are repeated. This calculation of the mean value is repeatedly performed up to a range between 359 degrees and 360 degrees. Δθ is not limited to 1 degree, may be smaller than 1 degree, or may be larger than 1 degree. The mean value represents a mean value in a specified range and means, for example, the above-described mean value in a specified range between n degrees and n+1 degrees. With this procedure, an approximate ellipse is drawn, and the mean value of the orientation strength in the radial direction of the approximate ellipse can be calculated.

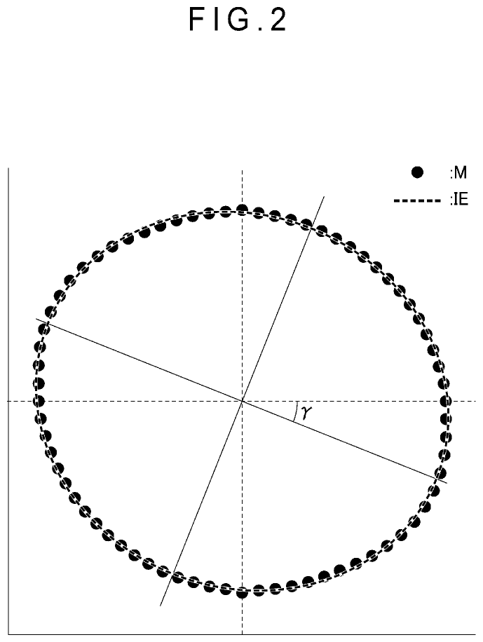

Referring to FIG. 2, FIG. 2 schematically illustrates an example of an angle distribution diagram of the mean amplitude of a pellicle film according to the exemplary embodiment. The angle distribution diagram of the mean amplitude illustrated in FIG. 2 is obtained by the above-described procedure on the basis of the power spectrum image. M in FIG. 2 denotes a mean value M and is a mean value in the specified range. An approximate ellipse is drawn from the angular distribution diagram of the mean amplitude by a set of data of the mean values M.

In step (S5), for the mean value of the orientation strength calculated in step (S4), an inclination of the approximate ellipse is calculated based on an elliptic equation to acquire an orientation angle. In step (S5), first, the set of calculated mean values is fitted by an elliptic equation. The elliptic equation is represented by a numerical formula (Numerical Formula 1) below. An ellipse represented by the numerical formula (Numerical Formula 1) below is an ellipse centered at the central coordinates, in which the major axis and the minor axis are inclined with respect to the x-axis and the y-axis, respectively. In the numerical formula (Numerical Formula 1) below, a, b, and c each represent a coefficient, and x and y are numerical values in the form of coordinates of an ideal ellipse.

$${ax}^{2} + bxy + {cy}^{2} = 1 \qquad ( Numerical Formula 1 )$$

The mean value calculated in step (S4) is represented by M, a deviation between the approximate ellipse obtained from the set of data of the mean values M and the ideal ellipse is used as an indicator, and an objective function represented by a numerical formula (Numerical Formula 2) below is minimized, thereby fitting the set of data of the mean values M into an ideal ellipse. In the numerical formula (Numerical Formula 2) below, a, b, and c each represent a coefficient, and X and Y are each a numerical value obtained by converting the mean value M into the form of a rectangular coordinate. X is represented by a numerical formula (Numerical Formula 3) below, and Y is represented by a numerical formula (Numerical Formula 4) below. M in the numerical formula (Numerical Formula 3) and the numerical formula (Numerical Formula 4) is a mean value M.

$$fun = \sum {( {aX}^{2} + bXY + {cY}^{2} - 1 )}^{2} \qquad ( Numerical Formula 2 )$$

$$X = M cos ( θ \times \frac{π}{180} ) \qquad ( Numerical Formula 3 )$$

$$Y = M sin ( θ \times \frac{π}{180} ) \qquad ( Numerical Formula 4 )$$

Subsequently, the numerical formula (Numerical Formula 2) is minimized by a fmincon function to determine the coefficients a, b, and c. The inclination (that is, the orientation angle γ) of the ellipse can be calculated from the determined coefficients a, b, and c by a numerical formula (Numerical Formula 5) below. The fmincon function used may be, for example, the fmincon function of analysis software (Mathworks, “MATLAB”).

$$γ = ( \frac{180}{π} ) \times ( \frac{arctan ( \frac{b}{a - c} )}{2} ) \qquad ( Numerical Formula 5 )$$

Referring back to FIG. 2, M denotes a mean value M as described above, and IE denotes an ideal ellipse. The orientation angle γ is calculated by determining the coefficients a, b, and c that give the minimum error between the set of data of the mean value M and the ideal ellipse.

In step (S6), a standard deviation of the orientation angle obtained in step (S5) is calculated. Specifically, the operations from step (S2) to step (S5) are repeatedly performed at a plurality of positions (for example, 10 fields of view), and the standard deviation of the orientation angle is measured from the mean values of the orientation angles at the plurality of positions.

In the pellicle film according to the exemplary embodiment, the standard deviation of the orientation angle of carbon nanotubes included in the pellicle film is 8.0 degrees or less, as measured by the operation method described above.

### Visible Light Transmittance

The visible light transmittance of the pellicle film according to the exemplary embodiment is preferably 50% or more, more preferably 60% or more, still more preferably 70% or more, and still further more preferably 80% or more.

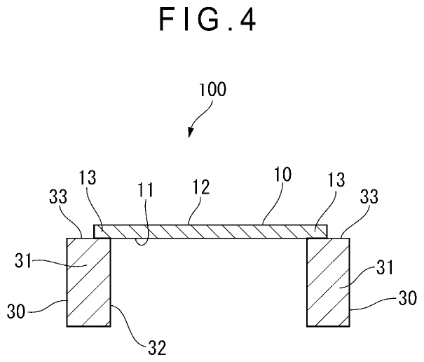

It is known that, in a pellicle film including carbon nanotubes (CNTs), there is a correlation between a light transmittance at a wavelength of 13.5 nm and a light transmittance at a wavelength of 550 nm (refer to, for example, Marina, Y, et al., “CNT EUV pellicle tunability and performance in a scanner-like environment”, Proc. SPIE 11609, Extreme Ultraviolet (EUV) Lithography XII, 116090Y, (23 Mar. 2021), FIG. 4(a); doi: 10.1117/12.2584519). In the pellicle film according to the exemplary embodiment, when the visible light transmittance determined by a measurement method described below is 50% or more, the EUV transmittance can be adjusted to 90% or more, and when the visible light transmittance is 80% or more, the EUV transmittance can be adjusted to 95% or more.

The visible light transmittance according to the exemplary embodiment is calculated by, for example, a numerical formula (Numerical Formula 6) below based on (1) an image of the pellicle film in a light-transmitting state, the image being composed of 700,000 pixels or more in an area of 14,300 mm² and captured on a side of the first pellicle film surface in a state where a side of the second pellicle film surface is placed on an image-capturing position and white light with a wavelength in a range from 400 nm to 750 nm is applied from the side of the second pellicle film surface, (2) an image of the image-capturing position in a bright state, the image being composed of the same number of pixels or more as that in (1) above in the area and obtained by imaging the image-capturing position not including the pellicle film in a state where the white light is applied, and (3) an image of the image-capturing position in a dark state, the image being composed of the same number of pixels or more as that in (1) above in the area and obtained by imaging the image-capturing position not including the pellicle film in a light-shielded state.

$$T = \{ ( Tp - Td ) / ( Tb - Td ) \} \times 100 \qquad ( Numerical Formula 6 )$$

In the numerical formula (Numerical Formula 6), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

Specifically, the visible light transmittance of the pellicle film according to the exemplary embodiment can be measured through the following step (S1T) to step (S7T).

Step (S1T): a step of preparing a pellicle film including carbon nanotubes and having a first pellicle film surface and a second pellicle film surface on a side opposite to the first pellicle film surface.

Step (S2T): a step of placing the prepared pellicle film on an image-capturing position such that the second pellicle film surface faces the image-capturing position.

Step (S3T): a step of applying white light with a wavelength in a range from 400 nm to 750 nm from a side of the second pellicle film surface of the placed pellicle film to transmit the white light through the pellicle film.

Step (S4T): a step of capturing an image with an image-capturing device, in a state where the white light is applied, on a side of the first pellicle film surface to which the white light is not applied, thereby acquiring an image of the pellicle film in a light-transmitting state, the image being composed of 700,000 pixels or more in an area of 14,300 mm².

Step (S5T): a step of capturing an image of the image-capturing position not including the pellicle film in a state where the white light is applied, thereby acquiring an image of the image-capturing position in a bright state, the image being composed of 700,000 pixels or more in an area of 14,300 mm².

Step (S6T): a step of capturing an image of the image-capturing position not including the pellicle film in a light-shielded state where the white light is not applied, thereby acquiring an image of the image-capturing position in a dark state, the image being composed of 700,000 pixels or more in an area of 14,300 mm².

Step (S7T): a step of calculating a visible light transmittance of the pellicle film by the numerical formula (Numerical Formula 6) based on the image of the pellicle film in the light-transmitting state (the image of the pellicle film in the light-transmitting state according to (1) above), the image of the image-capturing position in the bright state (the image of the image-capturing position in the bright state according to (2) above), and the image of the image-capturing position in the dark state (the image of the image-capturing position in the dark state according to (3) above.

In step (S7T), in the calculation of a visible light transmittance of the pellicle film and a standard deviation of the visible light transmittance, a transmittance map of the pellicle film is prepared based on the images acquired in steps (S4T), (S5T), and (S6T). The visible light transmittance (that is, the average value of the visible light transmittance) and the standard deviation of the visible light transmittance are determined based on the prepared transmittance map of the pellicle film. The image-capturing device used in the measurement of the visible light transmittance is not particularly limited, and may be, for example, a digital camera such as a digital single-lens reflex camera.

It is generally known that there is a correlation between the thickness of a pellicle film and the light transmittance of the pellicle film. In an example of the pellicle film according to the exemplary embodiment, when the visible light transmittance satisfies, for example, about 80%, the maximum value of the thickness of the pellicle film is, for example, 70 nm or less. In an example of the pellicle film according to the exemplary embodiment, when the visible light transmittance satisfies, for example, about 80%, the average value of the thickness of the pellicle film is, for example, 50 nm or less. For example, in an example of the pellicle film according to the exemplary embodiment, when the visible light transmittance is 70.8%, the average value of the thickness of the pellicle film is about 47 nm. The thickness of the pellicle film according to the exemplary embodiment can be measured with a scanning probe microscope. Considering excellent mechanical strength, the average value of the thickness of the pellicle film is preferably, for example, 30 nm or more, 35 nm or more.

The weight of the pellicle film per unit area is not particularly limited and is preferably in a range from 0.1 μg/cm² to 20 μg/cm². The weight of the pellicle film per unit area is more preferably 0.3 μg/cm² or more, still more preferably 0.4 μg/cm² or more. The weight of the pellicle film per unit area is more preferably 15 μg/cm² or less, still more preferably 10 μg/cm² or less. When the weight of the pellicle film per unit area is, for example, in a range from 0.1 μg/cm² to 20 μg/cm², the pellicle film tends to have excellent mechanical strength. In addition, high transparency to EUV of the pellicle film is likely to be ensured.

The pellicle film according to the exemplary embodiment is preferably a porous structure in which carbon nanotubes are deposited. Such a porous structure in which carbon nanotubes are deposited can be produced by an example of a preferred method for producing a pellicle film described later. In the pellicle film formed of such a porous structure in which carbon nanotubes are deposited, excellent mechanical strength of the pellicle film is likely to be obtained. In addition, high transparency to EUV of the pellicle film is likely to be ensured.

From the viewpoint of improving transparency to exposure light, the pellicle film according to the exemplary embodiment is preferably free-standing. The phrase “a pellicle film is free-standing” means a pellicle film that is free-standing on its own and means that the pellicle film is a film having a self-supporting property (also referred to as a free-standing film). That is, a free-standing pellicle film is a pellicle film that can retain its shape by itself even in the absence of a substrate or the like.

No particular limitation is imposed on a method for adjusting a pellicle film such that the standard deviation of the orientation angle of carbon nanotubes included in the pellicle film is 8.0 degrees or less, as measured by the operation method described above. The method may be, for example, a method for adjusting dispersion conditions for dispersing carbon nanotubes, centrifugal separation conditions for subjecting a dispersion liquid of carbon nanotubes to centrifugal separation, and the like in an example of a preferred method for producing a pellicle film described later.

### Method for Producing Pellicle Film

The method for producing a pellicle film according to the exemplary embodiment is not particularly limited as long as the standard deviation of the orientation angle of carbon nanotubes included in the pellicle film can satisfy the above-described numerical range, and various production methods can be employed. Examples of the method for producing a pellicle film according to the exemplary embodiment include a filtration method (a method in which a carbon nanotube dispersion liquid is filtered through a filter, and the resulting carbon nanotube film is then peeled off from the filter to obtain a pellicle film), an application method (a method in which a carbon nanotube dispersion liquid is applied onto a substrate, and the resulting carbon nanotube film is then peeled off from the substrate to obtain a pellicle film), and an etching method (a method in which a carbon nanotube film is formed on a wafer, and the wafer is then etched to obtain a pellicle film).

As described above, the method for producing a pellicle film according to the exemplary embodiment is not particularly limited. An example of a preferred method for producing a pellicle film according to the exemplary embodiment may be, for example, a production method including the following steps.

An example of a preferred method for producing a pellicle film according to the exemplary embodiment includes step (P1) of dispersing carbon nanotubes to obtain a first dispersion liquid of carbon nanotubes, step (P2) of dispersing the first dispersion liquid by centrifugal separation to separate aggregates of carbon nanotubes, subsequently collecting the supernatant to obtain a second dispersion liquid of carbon nanotubes, step (P3) of precipitating and depositing the second dispersion liquid of carbon nanotubes on an air-permeable member to obtain a film product of carbon nanotubes formed in the form of a mat on the air-permeable member, and step (P4) of removing the air-permeable member from the film product of carbon nanotubes to obtain a pellicle film.

First, in step (P1), carbon nanotubes are dispersed in a liquid serving as a dispersion medium to prepare a first dispersion liquid of carbon nanotubes in which the carbon nanotubes are dispersed in the liquid. The liquid may be a liquid containing water. The first dispersion liquid of carbon nanotubes may contain only carbon nanotubes as a dispersoid. The carbon nanotube dispersion liquid may contain, in addition to carbon nanotubes, various additives such as a dispersing agent for dispersing carbon nanotubes. In step (P1), the method for preparing the first dispersion liquid is not particularly limited. The first dispersion liquid can be prepared using a dispersing device. The first dispersion liquid may be prepared, for example, using a wet pulverization and dispersion device. In preparation of the first dispersion liquid using a wet pulverization and dispersion device, conditions for dispersion treatment using the wet pulverization and dispersion device may be, for example, dispersion conditions in which the pressure is in a range from 50 MPa to 200 MPa and the number of times of treatment is in a range from 1 to 10.

The weight of the carbon nanotubes per unit area may be, for example, in a range from 0.1 μg/cm² to 20 μg/cm² in terms of amount of carbon nanotubes included in the film product of carbon nanotubes prepared in step (P3).

Next, in step (P2), the first dispersion liquid of carbon nanotubes prepared in step (P1) is subjected to centrifugal separation with a centrifugal separator to separate aggregates of carbon nanotubes. Subsequently, the supernatant after centrifugal separation is collected to obtain a second dispersion liquid of carbon nanotubes. The supernatant includes carbon nanotubes. The conditions for centrifugal separation are not particularly limited. From the viewpoint of separating aggregates of carbon nanotubes, the conditions for centrifugal separation include, for example, a relative centrifugal acceleration of 100 kG or more and a treatment time of one hour or more.

Next, in step (P3), the supernatant, which is a second dispersion liquid collected in step (P2), is precipitated and deposited on an air-permeable member. For example, the supernatant collected in step (P2) is filtered through a filtration membrane serving as an air-permeable member to precipitate and deposit carbon nanotubes, thereby forming a film product of carbon nanotubes formed in the form of a mat on the filtration membrane. The filtration membrane is, for example, a filtration membrane made of nonwoven fabric. Specifically, for example, a filtration membrane made of nonwoven fabric, such as a membrane filter, is preferably used.

Subsequently, in step (P4), the filtration membrane is removed from the film product of carbon nanotubes formed in the form of a mat to obtain a pellicle film including carbon nanotubes. Before the filtration membrane is removed from the film product of fibers formed in the form of a mat or after the filtration membrane is removed from the film product of fibers formed in the form of a mat, a drying step may be performed, as needed. As needed, both a drying step and an annealing step may be performed or only an annealing step may be performed without performing a drying step.

The pellicle film obtained through step (P1) to step (P4) described above is a free-standing film.

### Pellicle

A pellicle according to the exemplary embodiment includes the pellicle film according to the exemplary embodiment described above and a support that has a frame and an opening surrounded by the frame and that supports the pellicle film.

The pellicle according to the exemplary embodiment will be described below with reference to the drawings.

Note that, in drawings for description with reference to the drawings in the present specification, some portions are illustrated in enlarged or reduced size for simplicity of explanation.

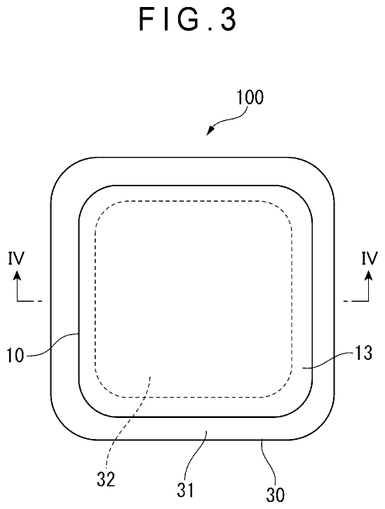

FIG. 3 is a plan view of a pellicle 100 when viewed from a surface on which a pellicle film 10 is disposed, and FIG. 4 is a sectional view of the pellicle 100 illustrated in FIG. 3. The pellicle 100 includes the pellicle film 10 and a support 30 that supports the pellicle film 10. The support 30 has a frame 31 and an opening 32 surrounded by the frame 31. The opening 32 extends from one surface of the support 30 toward the other surface of the support 30. The frame 31 and the opening 32 are each formed in a rectangular shape, and four corners of the contour of the frame 31 are rounded. The frame 31 has a supporting surface 33 that faces the pellicle film 10. The pellicle film 10 is the pellicle film 10 illustrated in FIG. 1. The pellicle film 10 is formed in a rectangular shape and has a first pellicle film surface 11 that faces the supporting surface 33 of the support 30 and a second pellicle film surface 12 on the side opposite to the first pellicle film surface 11. A peripheral portion 13 of the pellicle film 10 is fixed to a portion of the supporting surface 33 of the frame 31, so that the pellicle film 10 covers the opening 32 of the support 30.

The above-described pellicle film according to the exemplary embodiment is used as the pellicle film 10. Examples of the material of the support 30 include resin materials (such as polyethylene), metal materials (such as aluminum, aluminum alloys, magnesium alloys, stainless steel, and titanium), ceramic materials (such as SiC), and fiber-reinforced plastic materials (such as carbon fiber-reinforced plastics).

An example of the pellicle according to the exemplary embodiment has been described above with reference to FIGS. 3 and 4. The pellicle according to the exemplary embodiment is not limited thereto. The pellicle according to the exemplary embodiment may employ any of various forms as long as the advantages of the pellicle including the above-described pellicle film according to the exemplary embodiment are obtained. The shapes, dimensions, etc., of portions of the members constituting the pellicle according to the exemplary embodiment can be determined according to, for example, the dimensions of a photomask (not illustrated) for which the pellicle according to the exemplary embodiment is used.

For example, the pellicle film 10 and the support 30 of the pellicle 100 illustrated in FIGS. 3 and 4 are each formed in a rectangular shape. The pellicle according to the exemplary embodiment is not limited thereto and may be formed in any desired shape such as a circular, elliptical, or polygonal shape.

For example, in the pellicle 100 illustrated in FIGS. 3 and 4, the peripheral portion 13 of the pellicle film 10 is fixed to a portion of the supporting surface 33 of the support 30. The pellicle 100 is not limited thereto, and the peripheral portion 13 of the pellicle film 10 may be fixed to the entire surface of the supporting surface 33 of the support 30.

Alternatively, for example, in FIGS. 3 and 4, the pellicle film 10 and the support 30 may be fixed together by providing a bonding layer (not illustrated). The bonding layer is a layer provided according to need. Examples of materials constituting the bonding layer that may be used include, but are not particularly limited to, various adhesives such as an acrylic resin, an epoxy resin, a silicone resin, a polyimide resin, and a fluororesin; and carbon nanotubes.

### Method for Producing Pellicle

An example of a preferred method for producing a pellicle according to the exemplary embodiment includes a step of preparing a pellicle film according to the exemplary embodiment, a step of preparing a support that has a frame and an opening surrounded by the frame and that supports the pellicle film, and a step of providing the pellicle film on the support such that the pellicle film covers the opening and is supported by a supporting surface of the frame. The production method may optionally include a step of providing a bonding layer on at least a portion of the supporting surface of the frame.

The step of preparing a pellicle film according to the exemplary embodiment includes preparing the pellicle film according to the exemplary embodiment described above. The step of preparing a support includes preparing a support formed in a desired shape by a publicly known method using the foregoing material constituting the support. The step of providing the pellicle film includes disposing the pellicle film by a publicly known method such that the pellicle film covers the opening and is supported by the supporting surface of the frame. When a bonding layer is provided on at least a portion of the supporting surface of the frame, the pellicle film is disposed so as to be supported by the supporting surface of the frame with the bonding layer therebetween. When any adhesive is used for the bonding layer, the step of providing a bonding layer includes applying an adhesive to the supporting surface to provide the bonding layer including the adhesive. When carbon nanotubes are used as the bonding layer, the step of providing a bonding layer includes, for example, applying a dispersion liquid of carbon nanotubes to the supporting surface, and drying the dispersion liquid to provide the bonding layer including the carbon nanotubes.

The pellicle according to the exemplary embodiment is used, for example, by being disposed above a photomask to be spaced apart from the photomask such that the first pellicle film surface faces the photomask. Use of the pellicle according to the exemplary embodiment suppresses adhesion of foreign matter to the photomask. The pellicle according to the exemplary embodiment has excellent mechanical strength because the above-described pellicle film according to the exemplary embodiment is used. Accordingly, for example, damage to the pellicle during arrangement and transportation is suppressed. Furthermore, in the pellicle film according to the exemplary embodiment, variation in EUV transparency is reduced, while high transparency to EUV is ensured.

The invention is not limited to the above exemplary embodiments, and any of modifications, improvements, and the like are included in the invention as long as the objects of the invention can be achieved.

### EXAMPLES

The invention will be more specifically described below by way of Examples. However, the invention is not limited to these Examples.

### Example 1

### Preparation of Pellicle Film

Carbon nanotubes (hereinafter referred to as CNTs) having a diameter in a range from 0.2 nm to 50 nm and a length in a range from 1 μm to 250 μm were prepared as CNTs. The prepared CNTs were weighed such that the concentration in a first dispersion liquid of CNTs before dilution was 0.02% by mass. A surfactant serving as a dispersing agent was weighed such that the concentration in the first dispersion liquid of CNTs before dilution was 0.2% by mass. The weighed CNTs and the weighed surfactant were placed in water, and the CNTs were dispersed in water using a wet pulverization and dispersion device. As for dispersion conditions, the pressure was 70 MPa, and the number of times of treatment was three. Subsequently, dilution was performed such that the concentration of CNTs was 1 ppm to prepare the first dispersion liquid of CNTs. Next, the first dispersion liquid of CNTs was collected such that, as the amount of CNTs included in the pellicle film, the mass of CNTs (denoted by Amount of CNTs in Table 1) was the numerical value shown in Table 1.

Subsequently, the first dispersion liquid of CNTs was subjected to centrifugal separation with a centrifugal separator under the conditions of a relative centrifugal acceleration of 100 kG and a treatment time of two hours to separate aggregates of CNTs. After the centrifugal separation, the supernatant was collected. This supernatant was used as a second dispersion liquid of CNTs. Subsequently, the second dispersion liquid of CNTs was filtered through a membrane filter to form a mat-shaped film product of CNTs on the membrane filter. The mat-shaped film product of CNTs was then peeled off from the membrane filter. The film product of CNTs was heat-treated at 650 degrees C. for 30 minutes to prepare a pellicle film including CNTs. The pellicle film was a free-standing film.

### Evaluation of Pellicle Film

### Standard Deviation of Orientation Angle

For the standard deviation of the orientation angle of CNTs included in the prepared pellicle film, the standard deviation of the orientation angle was calculated according to step (S1) to step (S6) described above. Specifically, a surface (a first pellicle film surface or a second pellicle film surface) of the pellicle film was observed with a SEM (CrossBeam 550, manufactured by Carl Zeiss), and SEM image data on the surface of the pellicle film was acquired. Imaging conditions were an accelerating voltage of 1 kV, and a magnification of 10,000 times. The number of fields of view was 10. In acquiring a power spectrum image in step (S3) described above, the read SEM image was trimmed into a square size including 700×700 pixels. Furthermore, in drawing an approximate ellipse in step (S4) described above, Δθ for calculating the mean value was set to 1 degree.

### Bursting Strength of Pellicle Film

Bursting strength of the pellicle film was measured using a measuring device including a chamber having an opening that was partially open, a pressure sensor disposed inside the chamber, and a holder configured to hold a sample in the opening of the chamber. The pellicle film obtained in each example was held in the holder, nitrogen gas was caused to flow into the chamber, and a gas pressure was measured until the pellicle film held in the holder in the chamber was ruptured. A gas pressure at which the pellicle film was ruptured was defined as the bursting strength.

### Measurement of Visible Light Transmittance

For the visible light transmittance of the obtained pellicle film, a transmittance map of the pellicle film was prepared in accordance with step (S1T) to step (S7T) described above. The average value of the visible light transmittance was calculated by the numerical formula (Numerical Formula 6) based on the prepared transmittance map of the pellicle film. A mirrorless camera (“EOS R5”, manufactured by Canon Inc.) was used as an image-capturing device used in the procedure of step (S1T) to step (S7T) described above. The images acquired in steps (S4T), (S5T), and (S6T) described above are images that have an area of 14,300 mm² and are composed of 700,000 pixels. In Table 1, the average value of the visible light transmittance is denoted by AVE.

### Examples 2 to 4

Pellicle films of Examples were each prepared as in Example 1 except that the mass of CNTs included in the pellicle film was changed as described in Table 1, and the pellicle films were evaluated.

### Comparative Examples 1 and 2

Pellicle films of Comparative Examples 1 and 2 were each prepared as in Example 1 except that the mass of CNTs included in the pellicle film was changed as described in Table 1, and the centrifugal separation was not performed, and the pellicle films were evaluated.

TABLE 1

| | | Standard | | |
|---|---|---|---|---|
| | | deviation of | | Visible light |
| | Amount of | orientation | Bursting | transmittance |
| | CNTs | angle | strength | AVE |
| | (μg/cm²) | (°) | (Pa) | (%) |
| Example 1 | 0.4753 | 3.615 | 216.1 | 90.94 |
| Example 2 | 0.4994 | 1.080 | 222.8 | 90.50 |
| Example 3 | 0.5049 | 2.012 | 214.0 | 90.40 |
| Example 4 | 0.4775 | 2.551 | 152.1 | 90.90 |
| Comparative | 0.5016 | 8.323 | 68.86 | 90.46 |
| Example 1 | | | | |
| Comparative | 0.4994 | 38.63 | 68.90 | 90.50 |
| Example 2 | | | | |

The above results show that pellicle films in which the standard deviation of the orientation angle of carbon nanotubes included therein is 8.0 degrees or less have higher bursting strength than pellicle films in which the standard deviation exceeds 8.0 degrees. In particular, the pellicle films of Examples 1 and 4 are found to have high bursting strength, although the light transmittances thereof are higher than those of the pellicle films of Comparative Examples 1 and 2. The pellicle films of Examples 2 and 3 are found to have high bursting strength, although the light transmittances thereof are substantially the same as those of the pellicle films of Comparative Examples 1 and 2. Accordingly, the exemplary embodiment provides a pellicle film having excellent mechanical strength and a pellicle including the pellicle film. Moreover, the exemplary embodiment provides a method that enables measurement of a standard deviation of an orientation angle of carbon nanotubes included in a pellicle film having excellent mechanical strength.

What is claimed is:

1. A pellicle film having a porous structure,
wherein the pellicle film comprises carbon nanotubes,
the pellicle film has a first pellicle film surface and a second pellicle film surface on a side opposite to the first pellicle film surface, and
a standard deviation of an orientation angle of the carbon nanotubes is 8.0 degrees or less, the standard deviation being determined based on an approximate ellipse of a power spectrum image acquired by subjecting an image obtained by imaging the first pellicle film surface or the second pellicle film surface of the pellicle film to two-dimensional Fourier transform.

2. The pellicle film according to claim 1,
wherein the standard deviation of the orientation angle of the carbon nanotubes is in a range from 0.5 degrees to 8.0 degrees.

3. The pellicle film according to claim 1,
wherein the image obtained by imaging the first pellicle film surface or the second pellicle film surface is an image captured with a scanning electron microscope.

4. The pellicle film according to claim 1,
wherein the carbon nanotubes have a length in a range from 0.1 μm to 1,000 μm.

5. The pellicle film according to claim 1,
wherein the carbon nanotubes have a cross-sectional diameter in a range from 0.2 nm to 50 nm.

6. The pellicle film according to claim 1,
being a free-standing pellicle film.

7. A pellicle comprising:
the pellicle film according to claim 1; and
a support that has a frame and an opening surrounded by the frame and that supports the pellicle film.

8. A method for measuring a standard deviation of an orientation angle of carbon nanotubes included in a pellicle film having a porous structure, the method comprising:
preparing a pellicle film including carbon nanotubes and having a first pellicle film surface and a second pellicle film surface on a side opposite to the first pellicle film surface;
imaging the first pellicle film surface or the second pellicle film surface of the prepared pellicle film with a scanning electron microscope to acquire image data on the surface of the pellicle film;
subjecting the acquired image data to two-dimensional Fourier transform to acquire a power spectrum image;
drawing, for the acquired power spectrum image, an approximate ellipse from an angle distribution diagram of a mean amplitude and calculating a mean value of orientation strength in a radial direction of the approximate ellipse;
calculating, for the calculated mean value of the orientation strength, an inclination of the approximate ellipse based on an elliptic equation to acquire an orientation angle; and
calculating a standard deviation of the orientation angle.
